(19) United States
(12) Patent Application Publication
(10) Pub. No.: US 2026/0062797 A1
(43) Pub. Date: Mar. 5, 2026

(54) CONDUCTION COOLING PLATE USING FRICTION WELDING

(71) Applicant: Applied Materials, Inc., Santa Clara, CA (US)

(72) Inventors: Sathiyamurthi GOVINDASAMY, Coimbatore (IN); Brijesh RAJU, Santa Clara, CA (US); Suresh PALANISAMY, Coimbatore (IN); Harish Penmethsa, Coimbatore (IN)

(21) Appl. No.: 18/821,313

(22) Filed: Aug. 30, 2024

(51) Int. Cl. C23C 14/54; B23K 20/12

(52) U.S. Cl. CPC C23C 14/541; B23K 20/129

(57) ABSTRACT

In one embodiment, a cooling plate assembly for semiconductor processing is provided. The cooling plate includes a first plate, a second plate, and a middle plate. The first plate includes a first surface, an inlet disposed on the first surface, an outlet disposed on the first surface, and a first channel surface disposed opposite the first surface. The second plate includes a second surface, and a second channel surface. The second channel surface is disposed opposite the second surface. The middle plate is disposed between the first plate and the second plate. The middle plate includes a channel wall separating the first channel surface from the second channel surface, the first channel surface, the second channel surface. The channel wall defines a flow path from the inlet to the outlet. The first plate, the second plate, and the middle plate comprise copper.

### BACKGROUND

### Field

Embodiments of the present disclosure generally relate to physical vapor deposition (PVD) film formation on substrates in an electronic device fabrication process, and more particularly, to apparatus and methods for improving film uniformity with a compact cathode design.

### Description of the Related Art

Electronic device fabrication processes today often involve the use of a physical vapor deposition (PVD), or sputtering, process in a dedicated PVD chamber. The source of the sputtered material may be a planar or rotary sputtering target formed from pure metals, alloys, or ceramic materials. A magnet array, which is typically disposed within an assembly that is often referred to as a magnetron, is used to generate a magnetic field in the vicinity of the target. During processing, a high voltage is applied to the target to generate a plasma and enable the sputtering process. Because the voltage source is negatively biased, the target may also be referred to as the “cathode.” The high voltage generates an electric field inside the PVD chamber that is used to enable sputtering of the target material and generate and emit electrons from the target that are used to generate and sustain a plasma near the underside of the target.

During operation the power applied to the target can cause the target to erode in a non-uniform way as the power heats the target. Targets are costly consumables so pitting in the target due to high heat points reduces target life span and deposition uniformity. In addition, a deposition process can achieve a reduction in required time by increasing the power to the target. The increase in power to the target reduces target lifespan, which requires the targets to be replaced in shorter increments, reducing throughput.

Accordingly, there is a need in the art for apparatus and methods for improving target lifespan while increasing the speed at which material can be deposited.

### SUMMARY

In one embodiment, a cooling plate assembly for semiconductor processing is provided. The cooling plate includes a first plate, a second plate, and a middle plate. The first plate includes a first surface, an inlet disposed on the first surface of the first plate, an outlet disposed on the first surface of the first plate, and a first channel surface disposed opposite the first surface. The second plate includes a second surface, and a second channel surface. The second channel surface is disposed opposite the second surface. The middle plate is disposed between the first plate and the second plate. The middle plate includes a channel wall separating the first channel surface from the second channel surface, the first channel surface, the second channel surface. The channel wall defines a flow path from the inlet to the outlet. The first plate, the second plate, and the middle plate include copper.

In another embodiment, a target assembly for semiconductor processing is provided. The target assembly includes a target material, a backing plate, and a cooling plate assembly. The backing plate includes a target surface, and a cooling surface disposed opposite the target surface. The cooling plate assembly is disposed apart from the target material by the backing plate and is disposed in a wedge shape. The cooling plate assembly includes a first plate and a second plate. The first plate includes a first surface, an inlet disposed on a first surface of the first plate, an outlet disposed on the first surface of the first plate, and a first channel surface, the first channel surface disposed opposite the first surface. The second plate includes a second channel surface disposed opposite the second surface, and a middle plate disposed between the first plate and the second plate. The middle plate includes a channel wall separating the first channel surface from the second channel surface, the first channel surface, the second channel surface, and the channel wall defining a flow path from the inlet to the outlet. The first plate, the second plate, and the middle plate include copper and nickel.

In another embodiment, a method of forming a cooling plate assembly for semiconductor manufacturing is provided. The method includes forming a first plate, a second plate, and a middle plate into a wedge shape, wherein the first plate, the second plate, and the middle plate include copper. The method also includes friction welding a first channel surface of the first plate to the middle plate, and friction welding a second channel surface of the second plate to the middle plate. The middle plate is disposed between the first plate and the second plate. The friction welding forming a flow path defined by the first plate, the second plate, and the middle plate within a cooling plate assembly.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic top view of an exemplary substrate processing system, according to certain embodiments.

FIG. 2A is a side cross-sectional view of a physical vapor deposition (PVD) chamber that may be used in the substrate processing system of FIG. 1, according to certain embodiments.

FIG. 2B is an enlarged cross-sectional view of a portion of the PVD chamber of FIG. 2A, according to certain embodiments.

FIG. 2C is top view illustrating an overlay of a target and a substrate in relation to the PVD chamber of FIG. 2A, according to certain embodiments.

FIG. 3A is an isometric, exploded view of a cooling plate assembly, according to certain embodiments.

FIG. 3B is an isometric view of a cooling plate assembly, according to certain embodiments.

FIG. 4 is a top view of a thermal map of coolant within the middle plate of the cooling plate assembly, according to certain embodiments.

FIG. 5 is a cross sectional view of the cooling plate assembly, according to certain embodiments.

FIG. 6 is a flow diagram for forming the cooling plate assembly, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure provided herein generally relate to physical vapor deposition (PVD) of thin films on substrates in an electronic device fabrication process. More particularly, embodiments described herein provide apparatus and methods for improving film deposition uniformity, target life span, and target cooling enhancements. In some embodiments, the apparatus may include a cooling plate assembly to improve the film uniformity using a compact target, which enables increased deposition rates and improved heat flux. Embodiments of the disclosure provided herein can provide the cooling plate assembly with a larger coolant flux in order to enable enhanced deposition rates.

### Exemplary Substrate Processing System

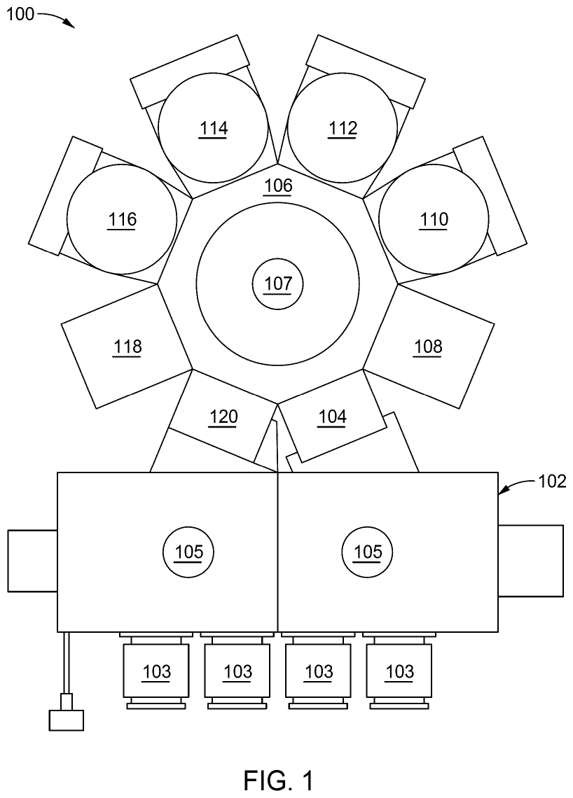

FIG. 1 is a schematic top view of an exemplary substrate processing system 100 (also referred to as a “processing platform”), according to certain embodiments. In certain embodiments, the substrate processing system 100 is particularly configured for processing large-area substrates, such as panels as described above. The substrate processing system 100 generally includes an equipment front-end module (EFEM) 102 for loading substrates into the processing system 100, a first load lock chamber 104 coupled to the EFEM 102, a transfer chamber 106 coupled to the first load lock chamber 104, and a plurality of other chambers coupled to the transfer chamber 106 as described in detail below. The EFEM 102 generally includes one or more robots 105 that are configured to transfer substrates from front opening unified pods (FOUPs) 103 to at least one of the first load lock chamber 104 or a second load lock chamber 120. Proceeding counterclockwise around the transfer chamber 106 from the first load lock chamber 104, the processing system 100 includes a first dedicated degas chamber 108, a first pre-clean chamber 110, a first deposition chamber 112, a second pre-clean chamber 114, a second deposition chamber 116, a second dedicated degas chamber 118, and the second load lock chamber 120. In certain embodiments, the transfer chamber 106 and each chamber coupled to the transfer chamber 106 are maintained at a vacuum state. As used herein, the term “vacuum” may refer to pressures less than 760 Torr, and will typically be maintained at pressures near 10⁻⁵ Torr (i.e., ˜10⁻³ Pa). However, some high-vacuum systems may operate below near 10⁻⁷ Torr (i.e., ˜10⁻⁵ Pa). In certain embodiments, the vacuum is created using a rough pump and/or a turbomolecular pump coupled to the transfer chamber 106 and to each of the one or more process chambers (e.g., process chambers 108-118). However, other types of vacuum pumps are also contemplated.

In certain embodiments, substrates are loaded into the processing system 100 through a door (also referred to as an “access port”), in the first load lock chamber 104 and unloaded from the processing system 100 through a door in the second load lock chamber 120. In certain embodiments, a stack of substrates is supported in a cassette disposed in the FOUPs 103, and are transferred therefrom by the robot 105 to the first load lock chamber 104. Once vacuum is pulled in the first load lock chamber 104, one substrate at a time is retrieved from the first load lock chamber 104 using a robot 107 located in the transfer chamber 106. In certain embodiments, a cassette is disposed within the first load lock chamber 104 and/or the second lock chamber 120 to allow multiple substrates to be stacked and retained therein before being received by the robot 107 in the transfer chamber 106 or robot 105 in the EFEM 102. However, other loading and unloading configurations are also contemplated.

In certain embodiments, only one substrate is processed within each pre-clean and deposition chamber at a time. Alternatively, multiple substrates may be processed at one time, such as four to six substrates. In such embodiments, the substrates may be disposed on a rotatable pallet within the respective chambers. In certain embodiments, the first and second pre-clean chambers 110, 114 are inductively coupled plasma (ICP) chambers for etching the substrate surface. However, other types of pre-clean chambers are also contemplated. In certain embodiments, one or both of the pre-clean chambers are replaced with a film deposition chamber that is configured to perform a PVD, chemical vapor deposition (CVD), or atomic layer deposition (ALD) process, such as deposition of silicon nitride.

In certain embodiments, the first and second deposition chambers 112, 116 are PVD chambers. In such embodiments, the PVD chambers may be configured to deposit copper, titanium, aluminum, gold, and/or tantalum. However, other types of deposition processes and materials are also contemplated.

### Exemplary PVD Chamber and Method of Use

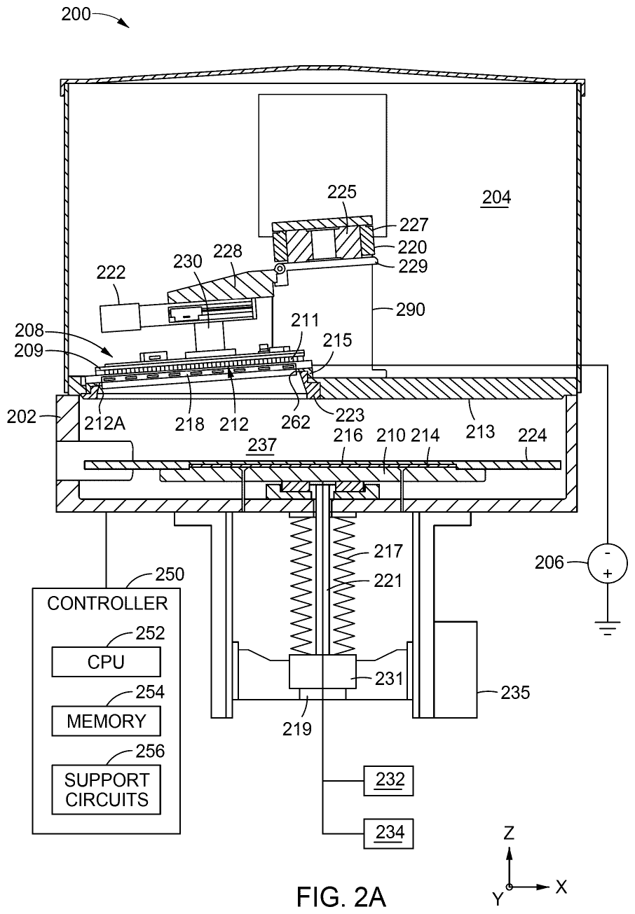

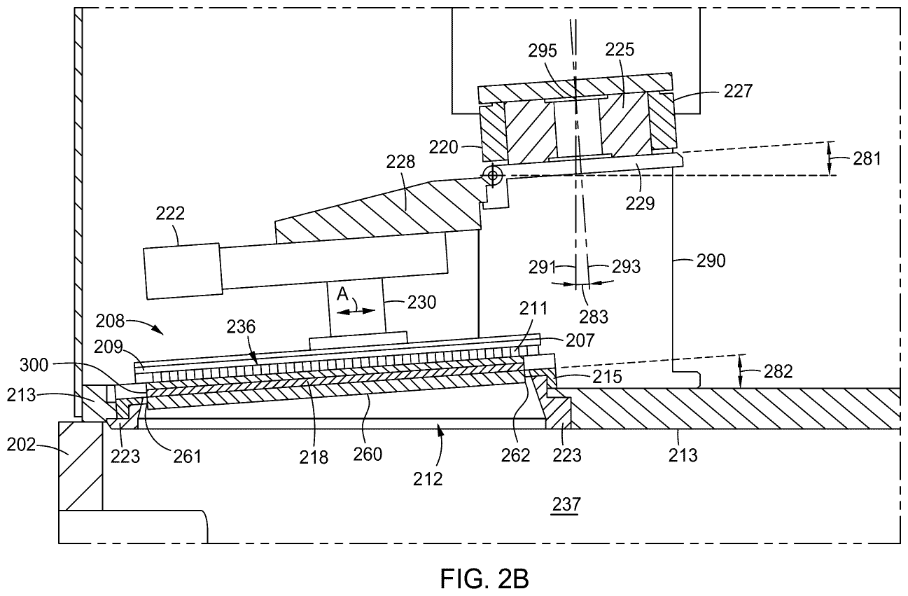

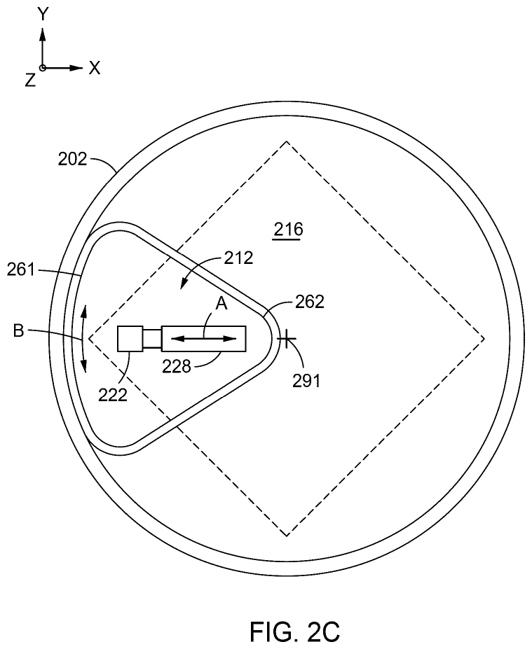

FIG. 2A is a side cross-sectional view of a PVD chamber 200 that may be used in the substrate processing system 100 of FIG. 1, according to certain embodiments. For example, the PVD chamber 200 may represent either one of the first or second deposition chambers 112, 116 shown in FIG. 1. Alternatively, the PVD chamber 200 may represent an additional deposition chamber. FIG. 2B is an enlarged cross-sectional view of a portion of the PVD chamber 200 of FIG. 2A, according to certain embodiments. FIGS. 2A-2B are, therefore, described together herein for clarity.

The PVD chamber 200 generally includes a chamber body 202, a lid assembly 204 coupled to the chamber body 202, a magnetron 208 coupled to the lid assembly 204, a pedestal 210 disposed within the chamber body 202, and a target assembly 212 disposed between the magnetron 208 and the pedestal 210. During processing, the interior of the PVD chamber 200, or processing region 237, is maintained at a vacuum pressure. The processing region 237 is generally defined by the chamber body 202 and the lid assembly 204, such that the processing region 237 is primarily disposed between the target assembly 212 and the substrate supporting surface of the pedestal 210.

The pedestal 210 has an upper surface 214 supporting a substrate 216. A clamp 224 is used to hold the substrate 216 on the upper surface 214. In certain embodiments, the clamp 224 operates mechanically. For example, the weight of the clamp 224 may hold the substrate 216 in place. In certain embodiments, the clamp 224 is lifted by pins that are movable relative to the pedestal 210 to contact an underside of the clamp 224.

A power source 206 is electrically connected to the target assembly 212 to apply a negatively biased voltage to the target assembly 212. In certain embodiments, the power source 206 is either a straight DC mode source or a pulsed DC mode source. However, other types of power sources are also contemplated, such as radio frequency (RF) sources.

The target assembly 212 includes a cooling plate assembly 300, a target material 260, and a backing plate 218, and is part of the lid assembly 204. A front surface of the target material 260 of the target assembly 212 defines a portion of the processing region 237. The backing plate 218 is disposed between the magnetron 208 and the target material 260 of the target assembly 212. In some embodiments, the target material 260 is bonded to the backing plate 218. The backing plate 218 is electrically insulated from a support plate 213 of the lid assembly 204 by use of an electrical insulator 215 to prevent an electrical short being created between the backing plate 218 and the support plate 213 of the grounded lid assembly 204.

A shield 223 is coupled to the support plate 213. The shield 223 prevents material sputtered from the target assembly 212 from depositing a film on the support plate 213. In some embodiments, the magnetron 208 and target assembly 212, which includes the target material 260 and backing plate 218, each have a triangular, wedge, and/or delta shape, such that a lateral edge of the target assembly 212 includes three corners (e.g., three rounded corners shown in FIG. 2C).

As shown in FIG. 2A, the magnetron 208 is disposed over a portion of the target assembly 212, and in a region of the lid assembly 204 that is maintained at atmospheric pressure. The magnetron 208 includes a magnet plate 209 (or yoke) and a plurality of permanent magnets 211 attached to the magnet plate 209. The magnet plate 209 has a triangular or delta shape with three corners (FIG. 2C). The magnets 211 are arranged in one or more closed loops. Each of the one or more closed loops will include magnets that are positioned and oriented relative to their pole (i.e., north (N) and south (S) poles) so that a magnetic field spans from one loop to the next or between different portions of a loop. The sizes, shapes, magnetic field strength, and distribution of the individual magnets 211 are generally selected to create a desirable erosion pattern across the surface of the target assembly 212 when used in combination with oscillation of the magnetron 208 as described below. In certain embodiments, the magnetron 208 may include a plurality of electromagnets 236 in place of the permanent magnets 211.

The magnetron 208 is coupled to the cooling plate assembly 300 by the magnet plate 209. The cooling plate assembly 300 is disposed between the backing plate 218 and the magnet plate 209. The cooling plate assembly 300 is disposed apart from the target material 260 by the backing plate 218.

In this example, the backside of the substrate 216 is in contact with the upper surface 214 of the pedestal 210. The temperature of the substrate 216 may be controlled using a temperature control system 232. In certain embodiments, the temperature control system 232 has an external cooling source that supplies coolant to the pedestal 210. In some examples, the cooling source may be replaced or augmented with a heating source to increase the workpiece temperature independent of the heat generated during the sputtering process. In certain embodiments, a radio frequency (RF) bias source 234 is electrically coupled to the pedestal 210 to bias the substrate 216 during the sputtering process. Alternatively, the pedestal 210 may be grounded, floated, or biased with only a DC voltage source. Biasing the substrate 216 can improve film density, adhesion, and material reactivity on the substrate surface.

A pedestal shaft 221 is coupled to an underside of the pedestal 210. A rotary union 219 is coupled to a lower end of the pedestal shaft 221 to provide rotary fluid coupling with the temperature control system 232 and rotary electrical coupling with the RF bias source 234.

In some embodiments, the substrate 216 is a panel. In some embodiments, the upper surface 214 of the pedestal 210 fits a single square or rectangular panel substrate having sides of about 500 mm or greater, such as 510 mm by 515 mm or 600 mm by 600 mm. However, apparatus and methods of the present disclosure may be implemented with many different types and sizes of substrates.

In certain embodiments, the pedestal 210 is rotatable about an axis 291 perpendicular to at least a portion of the upper surface 214 of the pedestal 210. In this example, the pedestal 210 is rotatable about a vertical axis, which corresponds to the z-axis. In certain embodiments, rotation of the pedestal 210 is continuous without indexing. In other words, a motor 231 driving rotation of the pedestal 210 does not have programmed stops for rotating the pedestal 210 to certain fixed rotational positions. Instead, the pedestal 210 is rotated continuously in relation to the target assembly 212 to improve film uniformity. In certain embodiments, the motor 231 is an electric servo motor. The motor 231 may be raised and lowered by a separate motor 235. The motor 235 may be an electrically powered linear actuator. A bellows 217 surrounds the pedestal shaft and forms a seal between the chamber body 202 and the motor 231 during raising and lowering of the pedestal 210.

An underside surface of the target assembly 212, which is defined by a surface of a target material 260, faces towards the upper surface 214 of the pedestal 210 and towards a front side of the substrate 216. The underside surface of the target assembly 212 faces away from the backing plate 218, which faces towards the atmospheric region or external region of the PVD chamber. In certain embodiments, the target material 260 of the target assembly 212 is formed from a metal for sputtering a corresponding film composition on the substrate 216. In one example, the target materials 260 may include a pure material or alloy containing elements selected from the group of copper (Cu), molybdenum (Mo), nickel (Ni), titanium (Ti), tantalum (Ta), aluminum (Al), cobalt (Co), gold (Au), silver (Ag), manganese (Mn), and silicon (Si). The materials deposited on a substrate 216 by the methods described herein may include pure metals, doped metals, metal alloys, metal nitrides, metal oxides, metal carbides containing these elements, as well as silicon containing oxides, nitrides or carbides.

As shown in FIG. 2B, a plane that is parallel to the underside of the target assembly 212 is tilted in relation to an upper surface of the support plate 213 by an angle 282. In other words, the plane of the target assembly 212 is tilted in relation to a plane of the upper surface 214 of the pedestal 210 and, thus, in relation to the front side of the substrate 216. Because respective bodies of each of the pedestal 210 and the target assembly 212 are generally planar, the target assembly 212 may also be referred to as being tilted relative to the pedestal 210, and vice versa. In certain embodiments, the angle 282 is about 2° to about 10°, such as about 3° to about 5°. As shown in FIG. 2A, the angle 282 is about 4°. As shown in FIG. 2A, the target assembly 212 is tilted downward in a direction from an inner radial edge 262 of the target assembly 212 to an outer radial edge 261 of the target assembly 212. The inner radial edge 262 is farther from the upper surface 214 of the pedestal 210 (e.g., vertically) compared to the outer radial edge 261. In one example, a target assembly 212 includes an edge that includes three corners. One of the three corners is coincident with the inner radial edge 262 and is positioned farther from the upper surface of the pedestal 210 compared to each of the two other corners due to the formed tilt angle. It is believed that tilt angles above the range provided herein may have target-to-substrate spacing that varies too much from the inner radial edge 262 to the outer radial edge 261, which can result in undesirable variation in film quality. In one example, an undesirable variation in film quality will include an undesirable variation in film roughness or grain size, or substrate center-to-edge uniformity. In another example, the undesirable variation in film quality can include an undesirable ratio of the amount of sputtered material provided to the surface of the substrate versus the amount of sputtered material provided to the shields that surround the substrate during a PVD process. Tilt angles below the range provided herein cause undesirable non-uniformity of the film. Therefore, the tilt angle window provided herein is able to achieve film deposition results that are improved over other conventional designs.

In this example, the pedestal 210 is substantially horizontal, or parallel to the x-y plane, whereas the target assembly 212 is non-horizontal, or tilted in relation to the x-y plane. However, other non-horizontal orientations of the pedestal 210 are also contemplated.

A first actuator 220 is coupled to the lid assembly 204 and to the magnetron 208 for oscillating the magnetron 208 in a circumferential direction B (shown in FIG. 2C) centered about the rotational axis 293 of the first actuator 220 that is positioned near and at an angle 283 to the center axis 291. In some embodiments, the rotational axis 293 is perpendicular to the surface of the target assembly 212. In some embodiments, as illustrated in FIG. 2B, the rotational axis 293 is disposed a distance from the magnetron 208 (e.g., nearest edge 207 of the magnetron 208) when measured relative to a plane that is perpendicular to the rotational axis 293. The first actuator 220 has a rotor 225 and a stator 227. The stator 227 is coupled to a support post 290 that is coupled to the support plate 213 of the lid assembly 204. The rotor 225 is coupled to a mounting plate 229 that is coupled to the magnetron 208 through a hinge 228 (described in detail below). In some configurations, the center axis 291 of the support post 290 is centered in relation to the chamber body 202 and the lid assembly 204. In certain embodiments, the first actuator 220 is an electric motor. Alternatively, a pneumatic motor may be used. In some examples, the first actuator 220 may be a servo or stepper motor. In some examples, the first actuator 220 may be a direct drive motor, a belt drive motor, or a gear drive motor. In certain embodiments, the first actuator 220 has program stops corresponding to the circumferential oscillation angle 295. In certain embodiments, the first actuator 220 is an electric or pneumatic rotary actuator corresponding to the circumferential oscillation angle 295. However, other types of motors/actuators are also contemplated.

In the illustrated embodiments, the hinge 228 is used to couple a support body 230 of the magnetron 208 to the first actuator 220. The hinge 228 enables the magnetron 208 to be lifted and rotated out of the way of the backing plate 218. This provides easy access to the underside of the magnetron 208 and the topside of the backing plate 218 for performing maintenance, such as replacing the target assembly 212.

A system controller 250, such as a programmable computer, is coupled to the PVD chamber 200 for controlling the PVD chamber 200 or components thereof. For example, the system controller 250 may control the operation of the PVD chamber 200 using direct control of the power source 206, the magnetron 208, the pedestal 210, cooling of the backing plate 218, the first actuator 220, the second actuator 222, the temperature control system 232, and/or the RF bias source 234, or using indirect control of other controllers associated therewith. In operation, the system controller 250 enables data acquisition and feedback from the respective components to coordinate processing in the PVD chamber 200.

The system controller 250 includes a programmable central processing unit (CPU) 252, which is operable with a memory 254 (e.g., non-volatile memory) and support circuits 256. The support circuits 256 (e.g., cache, clock circuits, input/output subsystems, power supplies, etc., and combinations thereof) are conventionally coupled to the CPU 252 and coupled to the various components of the PVD chamber 200.

In some embodiments, the CPU 252 is one of any form of general purpose computer processor used in an industrial setting, such as a programmable logic controller (PLC), for controlling various monitoring system component and sub-processors. The memory 254, coupled to the CPU 252, is non-transitory and is typically one or more of readily available memory such as random access memory (RAM), read only memory (ROM), floppy disk drive, hard disk, or any other form of digital storage, local or remote.

Herein, the memory 254 is in the form of a computer-readable storage media containing instructions (e.g., non-volatile memory), that when executed by the CPU 252, facilitates the operation of the PVD chamber 200. The instructions in the memory 254 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

In operation, the PVD chamber 200 is evacuated and back filled with argon gas. The power source 206 applies a negative bias voltage to the target assembly 212 to generate an electric field inside the chamber body 202. The electric field acts to attract gas ions, which due to their collision with the exposed surface of the target assembly 212, generates electrons that enable a high-density plasma to be generated and sustained near the underside of the target assembly 212. The plasma is concentrated near the surface of target material 260 due to the magnetic field produced by the magnetron 208. The magnetic field forms a closed-loop annular path acting as an electron trap that reshapes the trajectories of the secondary electrons ejected from the target material 260 into a cycloidal path, greatly increasing the probability of ionization of the sputtering gas within the confinement zone. The plasma confined near the underside of the target assembly 212 contains argon atoms, positively charged argon ions, free electrons, and neutral atoms (i.e., unionized atoms) sputtered from the target material 260. The argon ions in the plasma strike the target surface and eject atoms of the target material, which are accelerated towards the substrate 216 to deposit a thin film on the substrate surface.

Inert gases, such as argon, are usually employed as the sputtering gas because they tend not to react with the target material or combine with any process gases and because they produce higher sputtering and deposition rates due to their relatively high molecular weight.

FIG. 2C is a top view illustrating an overlay of the target assembly 212 and the substrate 216 in relation to the chamber body 202 of FIG. 2A, according to certain embodiments. In certain embodiments, the outer radial edge 261 of the target assembly 212 extends a distance of about 1 inch to about 3 inches, such as about 1.5 inches beyond a corner of the substrate 216. In certain embodiments, the inner radial edge 262 of the target assembly 212 is spaced a distance of about 0.25 inches to about 0.75 inches, such as about 0.5 inches from the center axis 291 of the support post 290, which may be coincident with a radial center of the chamber body 202.

As illustrated in FIG. 2C, the target assembly 212 is oriented such that a tip of a corner of the triangular or delta shaped target is at or adjacent to the center axis 291. When viewed in a planar orientation view, as shown in FIG. 2C, the surface area of the target assembly 212 is less than the surface area of the substrate 216. In some embodiments, a surface area of the upper surface of the pedestal is greater than a surface area of the front surface of the target assembly 212. In some embodiments, the ratio of the surface areas of the front surface of the target assembly 212 to the deposition surface of the substrate 216 (e.g., upper surface of the substrate) is between about 0.1 and about 0.4.

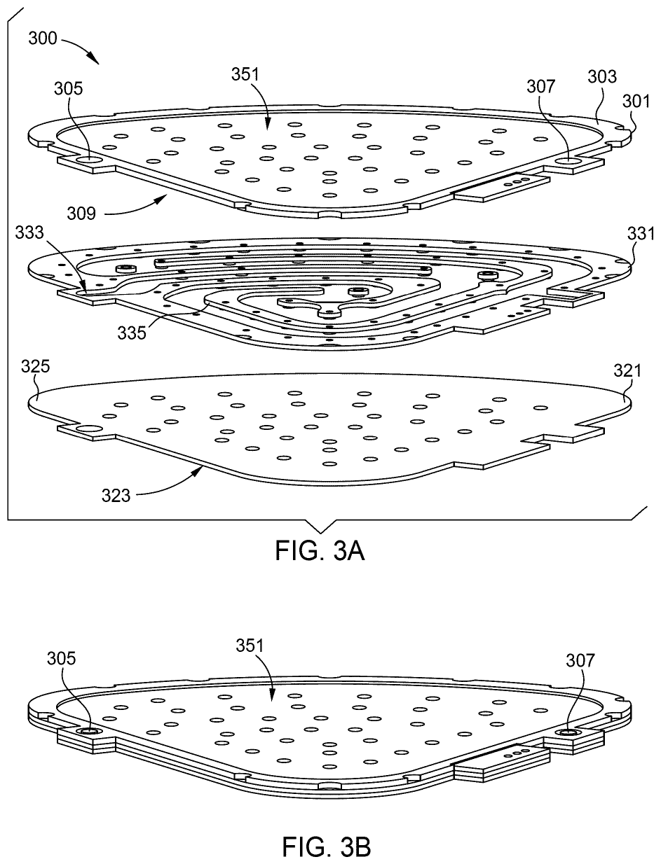

FIG. 3A is an isometric exploded view of the cooling plate assembly 300, according to certain embodiments. FIG. 3B is an isometric view of the cooling plate assembly 300, according to certain embodiments.

The cooling plate assembly 300 includes a first plate 301, a second plate 321, and a middle plate 331. The first plate 301 includes a first surface 303, an inlet 305, an outlet 307, and a first channel surface 309. The first channel surface 309 is disposed opposite the first surface 303. The inlet 305 and the outlet 307 are both disposed on the first surface 303 of the first plate 301. The second plate 321 includes a second surface 323 and a second channel surface 325. The second channel surface 325 is disposed opposite the second surface 323. The inlet 305 is coupled to a coolant source and the outlet 307 is coupled to an outlet line that translates heated coolant from the cooling plate assembly 300 to a heat dissipation unit (not shown).

The middle plate 331 is disposed between the first plate 301 and the second plate 321. The middle plate 331 includes a flow path 333 and channel walls 335. The channel walls 335 separate the first channel surface 309 from the second channel surface 325. The first channel surface 309, the second channel surface 325, and the channel walls 335 define the flow path 333 from the inlet 305 to the outlet 307.

As shown in FIG. 3B, the cooling plate assembly 300 further includes one or more mount holes 351. The mount holes 351 are apertures through the first plate 301, the second plate 321, and the middle plate 331. The middle plate 331 separates the mount holes 351 from the flow path 333. The plurality of mount holes 351 enable the backing plate 281 and target material 260 to be switched to a new backing plate 281 and target material 260 without disconnecting any coolant lines from the cooling plate assembly 300, reducing downtime of a chamber. Hardware is disposed through the plurality of mount holes 351 and secures the cooling plate assembly 300 to the backing plate 218. For example, a bolt is disposed though one of the plurality of mount holes 351 and threaded into the backing plate 218 to hold the cooling plate assembly 300 to the backing plate 218.

The first plate 301, the second plate 321, and the middle plate 331 of the cooling plate assembly 300 form a solid body. The first plate 301, the second plate 321, and the middle plate 331 are friction welded together. The friction welded cooling plate assembly 300 allows for a reduced number of required seals to ensure coolant flowing through the cooling plate assembly 300, along the flow path 333, does not leak. Further, by reducing the number of seals, there are less seal failure points that require maintenance.

The first plate 301, the second plate 321, and the middle plate 331 of the cooling plate assembly 300 form a wedge shape. For example, each of the first plate 301, the second plate 321, and the middle plate 331 are disposed in a wedge shape. The first plate 301, the second plate 321, and the middle plate 331 are formed of the same plate material. The plate material has a thermal conductivity of 200 W/m K or greater. The plate material has a density of 8 grams/centimeters3 or greater. The plate materials has a specific heat of about 380 J/kg K or greater. In some embodiments, the plate material includes copper. In some embodiments, the plate material includes copper and chromium. In some embodiments, the plate material includes copper, chromium, nickel, and silicon. For example, the first plate 301, the second plate 321, and the middle plate 331 each include copper. In some embodiments, the first plate 301, the second plate 321, and the middle plate 331 each include copper and nickel and the first plate 301, the second plate 321, and the middle plate 331 are the same material.

The material of the first plate 301, the second plate 321, and the middle plate 331 as described herein enables more efficient cooling of the backing plate 218 and target material 260 during operation (FIG. 2B). As described below, the material includes copper and enables the cooling plate assembly 300 to be friction welded together such that the flow path 333 is closer to the backing plate 218 than conventional cooling plate assemblies that utilized polymer seals between the first plate 301, the second plate 321, and the middle plate 331. This enhanced proximity is enabled because the friction welds form a sealed flow path 333 without the need of polymer seals between each of the first plate 301, the second plate 321, and the middle plate 331. For example, the cooling plate assembly 300 is a seal-less assembly in that there is not a polymer seal between of first plate 301, the second plate 321, and the middle plate 331.

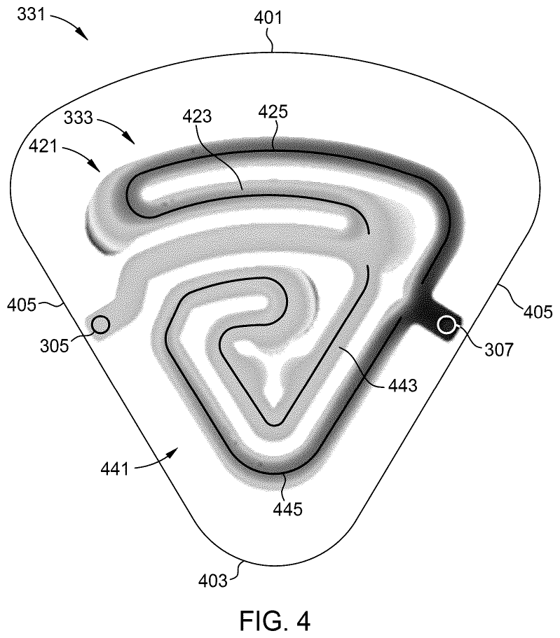

FIG. 4 is a top view of a thermal map of coolant within the middle plate 331, according to certain embodiments. As shown the lighter areas illustrate a lower temperature as coolant enters the inlet 305 and the darker areas show higher temperatures as the coolant leaves the outlet 307. While the coolant is shown entering the inlet 305 and leaving the outlet 307, the inlet 305 and outlet 307 may be switched in some embodiments.

The flow path 333 is configured to keep the target material 260 (FIG. 2B) below 250° C. when the coolant is DI water flowed at about 25 liters per minute. For example, when the magnetron 208 (FIG. 2A) is supplied 30 KW to generate plasma, the coolant is 18° C. DI water flowed at about 75psi at 25 liters per minute and the target material 260 (FIG. 2B) includes copper, the target material 260 is kept at about 100° C. or less. In another example, when the magnetron 208 (FIG. 2A) is supplied 30 KW to generate plasma, the coolant is 18° C. DI water flowed at about 75 psi at 25 liters per minute and the target material 260 (FIG. 2B) includes titanium, the target material 260 is kept at about 210° C. or less.

The middle plate 331 includes a major curved surface 401, a minor curved surface 403, and one or more side surfaces 405. The one or more side surfaces 405 are disposed between the major curved surface 401 and the minor curved surface 403. The one or more side surfaces 405, the major curved surface 401, and the minor curved surface 403 are disposed about perpendicular to the first plate 301 (FIG. 3A). The one or more side surfaces 405, the major curved surface 401, and the minor curved surface 403 form a wedge shape with the middle plate 331.

The middle plate 331 includes a first region 421 disposed proximate the major curved surface 401 and a second region 441 disposed proximate the minor curved surface 403. The first region 421 includes a first sub flow path 423 of the flow path 333. The second region 441 includes a second sub flow path 443 of the flow path 333. The first sub flow path 423 and the second sub flow path 443 are sized and shaped to have an about equal heat flux. For example as coolant flows through the flow path 333, the heat removed by the coolant flowing through first sub flow path 423 is about equal to the heat removed by the coolant flowing through second sub flow path 443. The first sub flow path 423 and the second sub flow path 443 enable the target assembly 212 to operate at higher energy, thereby increasing deposition rate without exceeding a thermal threshold of the target assembly 212.

The first sub flow path 423 includes a first length 425. The first length 425 is about 1,200 millimeters to about 1,600 millimeters. The second sub flow path 443 includes a second length 445. The second length 445 is about 1,200 millimeters to about 1,600 millimeters. In some embodiments, the second sub flow path 443 is configured to have fewer changes in direction than the first sub flow path 423. In some embodiments, the first length 425 is about equal to the second length 445.

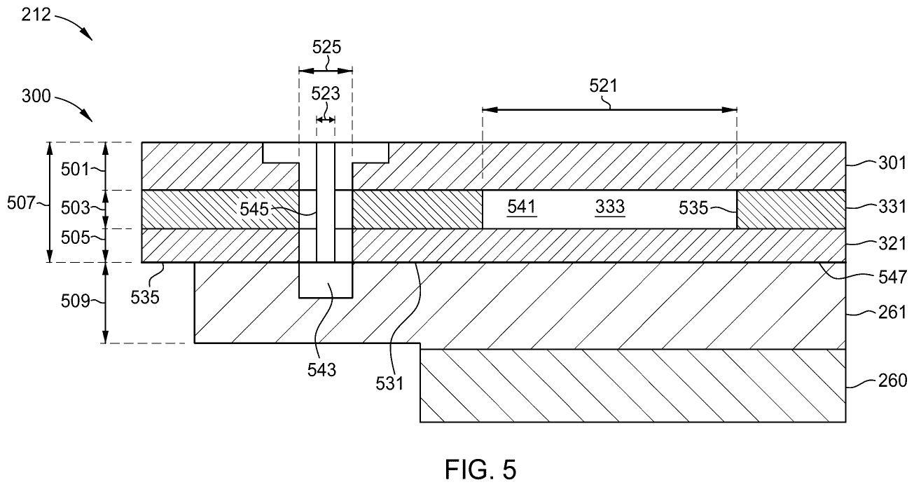

FIG. 5 is a cross sectional view of the target assembly 212, according to certain embodiments. The flow path 333 of the cooling plate assembly 300 includes a cross section 541. The cross section 541 has an area of about 170 square millimeters to about 200 square millimeters. The flow path 333 of the cooling plate assembly 300 defines a volume of 0.5 liters or more. In some embodiments, the cross section 541 varies along the flow path 333. The cross section 541 is defined by a width 521 and a height 535. The width 521 of the flow path 333 is about 37 millimeters to about 42 millimeters. The height 535 of the flow path 333 is about 4.0 millimeters to about 6.0 millimeters, foe example, about 5 millimeters. The flow path 333 is separated from the backing plate 218 by the second plate 321.

As shown in FIG. 5, the first plate 301 has a thickness 501 of about 2.1 mm to about 3.0 millimeters. The second plate 321 has a thickness 505 of about 2.1 mm to about 3.0 millimeters. The middle plate 331 has a thickness 503 of about 4.0 millimeters to about 6.0 millimeters. In some embodiments, the thickness 503 of the middle plate 331 is at least 1.0 millimeter greater than the thickness 501 and the thickness 503. The increase in thickness of the middle plate 331 allows for a larger cross section of the flow path 333 thereby allowing more coolant flow and enhancing the cooling ability of the cooling plate assembly 300. In some embodiments, the thicknesses 501, 503, 505 are about equal. In some embodiments, a total thickness 507 of the cooling plate assembly 300 is less than 11 millimeters.

The backing plate 218 includes a cooling surface 531 and a thickness 509. The thickness 509 is about 2.0 millimeters to about 10 millimeters. The cooling surface 531 is coupled to the cooling plate assembly 300. The cooling surface 531 is coupled to a target surface 533 of the second plate 321 of the cooling plate assembly 300. The target surface 533 is disposed opposite the second channel surface 325.

In some embodiments, a foil layer 547 is disposed between the backing plate 218 and the second plate 321, along the cooling surface 531 of the backing plate 218. The foil layer 547 may be a copper foil or an aluminum foil to enhance thermal conduction. In some embodiments, the backing plate 218 is formed of the same material as one or more of the first plate 301, the second plate 321, and/or the middle plate 331.

The backing plate 218 also includes a plurality of mounts 543 disposed through the plurality of mount holes 351 disposed through the cooling plate assembly 300. The mounts 543 may be threaded recess so the cooling plate assembly 300 can be bolted to the backing plate 218. Each mount hole 351 of the plurality of mount holes 351 is defined by a mount hole wall 545 of the middle plate 331. The mount hole wall 545 has a brinell hardness of about 185 or greater. The mount hole wall 545 defines a mount hole diameter 523 of about 2 millimeters to about 6 millimeters. The plurality of mount holes 351 each include a thickness 525 of the material of the middle plate 331 between the flow path 333 and the mount hole wall 545 of the mount hole 351. For example, the thickness 525 of the material of the middle plate 331 is about 5 millimeters or less. I

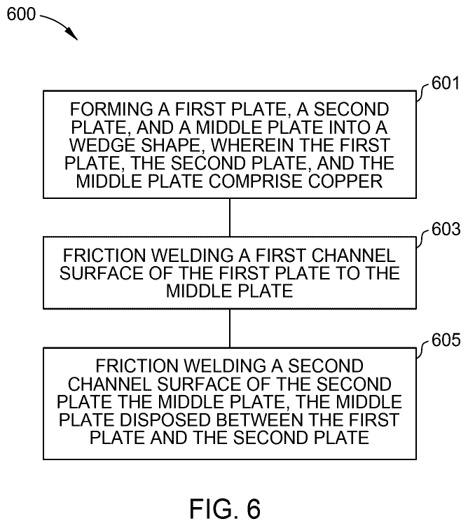

FIG. 6 is a flow diagram of a method 600 of forming the cooling plate assembly 300, according to certain embodiments. At operation 601, the first plate 301, the second plate 321, and the middle plate 331 are each formed into a wedge shape. The first plate 301, the second plate 321, and the middle plate 331 each include copper.

At operation 603, the first channel surface 309 of the first plate 301 is friction welded to the middle plate 331.

At operation 605, the second channel surface 325 of the second plate 321 is friction welded to the middle plate 331. The friction welding forms the flow path 333 defined by the first plate 301, the second plate 321, and the middle plate 331 within the cooling plate assembly 300.

In some embodiments, the friction welding of the first plate 301 and the middle plate 331 is friction stir welding. In some embodiments, the friction welding of the first plate 301 and the middle plate 331 and the friction welding of the second plate 321 and the middle plate 331 occurs simultaneously. For example, the first plate 301, the second plate 321, and the middle plate 331 are welded together simultaneously. When using friction stir welding, the welded parts are less likely to leak when compared to other welding processes. Further, friction stir welding causes less shrinkage and deformation because less heat is generated, allowing for a reduction in post machining processes.

In some embodiments, the method 600 of forming the cooling plate assembly 300 also includes forming the plurality of mount holes 351 disposed through the cooling plate assembly 300. The plurality of mount holes 351 are disposed through a welded portion of the cooling plate assembly 300.

In some embodiments, the method 600 of forming the cooling plate assembly 300 also includes forming inlet 305 and the outlet 307 in the first plate 301. The inlet 305 is formed such that the inlet 305 is in fluid communication with the outlet 307 through the first sub flow path 423 and the second sub flow path 443 of the flow path 333.

Benefits of the present disclosure include enhanced target assembly cooling; reduced or eliminated seal within a cooling plate; enhanced target material life; more uniform deposition; higher deposition rates; and increased throughput. As an example, the friction welded cooling plate assembly allows for enhanced cooling capabilities, enhanced deposition rates, and reduced number of potential seal failures, thereby reducing potential sources of non-uniformity and reductions in through-put.

It is contemplated that one or more aspects disclosed herein may be combined. As an example, one or more aspects, features, components, operations and/or properties of the target assembly 212, cooling plate assembly 300, first plate 301, second plate 321, middle plate 331, and/or the method 600 may be combined.

While the foregoing is directed to embodiments of the present disclosure, other and further embodiments of the disclosure may be devised without departing from the basic scope thereof, and the scope thereof is determined by the claims that follow.

What is claimed is:

1. A cooling plate assembly for semiconductor processing, the cooling plate comprising:
a first plate comprising:
a first surface;
an inlet disposed on the first surface of the first plate;
an outlet disposed on the first surface of the first plate; and
a first channel surface, the first channel surface disposed opposite the first surface;
a second plate comprising:
a second surface; and
a second channel surface, the second channel surface disposed opposite the second surface; and
a middle plate disposed between the first plate and the second plate, the middle plate comprising a channel wall separating the first channel surface from the second channel surface, the first channel surface, the second channel surface, and the channel wall defining a flow path from the inlet to the outlet, wherein the first plate, the second plate, and the middle plate comprise copper.

2. The assembly of claim 1, wherein the middle plate is disposed in a wedge shape and the first plate, the second plate, and the middle plate are the same material.

3. The assembly of claim 1, wherein the middle plate further comprises:
a major curved surface;
a minor curved surface; and
one or more side surfaces, the one or more side surfaces disposed between the major curved surface and the minor curved surface, the one or more side surfaces, the major curved surface, and the minor curved surface disposed about perpendicular to the first plate, the one or more side surfaces, the major curved surface, and the minor curved surface forming a wedge shape.

4. The assembly of claim 3, wherein the middle plate further comprises:
a first region disposed proximate the major curved surface, the first region comprising a first sub flow path of the flow path; and
a second region disposed proximate the minor curved surface, the second region comprising a second sub flow path of the flow path.

5. The assembly of claim 1, wherein the flow path comprises:
a first sub flow path; and
a second sub flow path, the first sub flow path and second sub flow path sized and shaped to have an about equal heat flux.

6. The assembly of claim 1, wherein a material of the first plate, the second plate, and the middle plate each comprise:
a thermal conductivity of 200 W/m K or greater; and
a density of 8 grams/centimeters³ or greater.

7. The assembly of claim 6, wherein the material of the first plate, the second plate, and middle plate each comprise a specific heat of about 380 J/kg K or greater; and a thickness of the first plate, the second plate, and the middle plate are about equal.

8. A target assembly for semiconductor processing, the target assembly comprising:
a target material;
a backing plate comprising:
a target surface; and
a cooling surface disposed opposite the target surface; and
a cooling plate assembly, the cooling plate assembly disposed apart from the target material by the backing plate, the cooling plate assembly disposed in a wedge shape, the cooling plate assembly comprising:
a first plate comprising:
a first surface;
an inlet disposed on a first surface of the first plate;
an outlet disposed on the first surface of the first plate; and
a first channel surface, the first channel surface disposed opposite the first surface;
a second plate comprising:
a second channel surface disposed opposite the second surface; and
a middle plate disposed between the first plate and the second plate, the middle plate comprising a channel wall separating the first channel surface from the second channel surface, the first channel surface, the second channel surface, and the channel wall defining a flow path from the inlet to the outlet, wherein the first plate, the second plate, and the middle plate comprise copper and nickel.

9. The target assembly of claim 8, wherein the cooling plate assembly is coupled to the backing plate by a plurality of mounts disposed through a plurality of mount holes disposed through the cooling plate assembly, each mount hole of the plurality of mount holes is defined by a mount hole wall in the middle plate, the mount hole wall comprising a brinell hardness of about 185 or greater.

10. The target assembly of claim 8, wherein the flow path comprises:
a first sub flow path comprising a first length; and
a second sub flow path comprising a second length, the first length being about equal to the second length.

11. The target assembly of claim 10, wherein the flow path comprises a cross section, the cross section comprising an area of between 170 square millimeters to about 200 square millimeters.

12. The target assembly of claim 8, wherein the flow path is separated from the backing plate by the second plate.

13. The target assembly of claim 8, wherein the middle plate has a thickness of about 5 millimeters.

14. The target assembly of claim 8, wherein the middle plate has a thickness greater than a thickness of the first plate and a thickness of the second plate.

15. The target assembly of claim 8, wherein a plate material of the first plate comprises a specific heat of about 370 J/kg K to about 400 J/kg K.

16. A method of forming a cooling plate assembly for semiconductor manufacturing, the method comprising:
forming a first plate, a second plate, and a middle plate into a wedge shape, wherein the first plate, the second plate, and the middle plate comprise copper;
friction welding a first channel surface of the first plate to the middle plate; and
friction welding a second channel surface of the second plate to the middle plate, the middle plate disposed between the first plate and the second plate, the friction welding forming a flow path defined by the first plate, the second plate, and the middle plate within a cooling plate assembly.

17. The method of claim 16, wherein the friction welding of the first plate and the middle plate is friction stir welding.

18. The method of claim 16, wherein the friction welding of the first plate and the middle plate and the friction welding of the second plate and the middle plate occurs simultaneously.

19. The method of claim 16, further comprising forming a plurality of plurality of mount holes disposed through the cooling plate assembly, the plurality of plurality of mount holes disposed through a welded portion of the cooling plate assembly.

20. The method of claim 16, further comprising forming an inlet and an outlet in the first plate, the inlet in fluid communication with the outlet through a first sub flow path and a second sub flow path of the flow path.
